(19) United States
(12) Patent Application Publication
(10) Pub. No.: US 2026/0082839 A1
(43) Pub. Date: Mar. 19, 2026

(54) METHOD FOR FORMING CONTACT HOLE AND METHOD FOR MANUFACTURING SEMICONDUCTOR DEVICE

(71) Applicant: CANON KABUSHIKI KAISHA, Tokyo (JP)

(72) Inventors: AKIRA MATSUZAKI, Kanagawa (JP); MAYU ISHIKAWA, Kanagawa (JP); KOJI HARA, Chiba (JP)

(21) Appl. No.: 19/326,278

(22) Filed: Sep. 11, 2025

(30) Foreign Application Priority Data
Sep. 18, 2024 (JP) 2024-160825

(51) Int. Cl. H01L 21/311; G03F 7/00

(52) U.S. Cl. CPC H10P 50/73; G03F 7/0015; G03F 7/0035; G03F 7/70033; G03F 7/70091

(57) ABSTRACT

A method for forming a contact hole includes forming a light shielding film on a substrate, forming a first film having a flat upper surface by applying a precursor on the substrate in such a manner that an application amount of the precursor is smaller on the light shielding film than on another portion, and patterning the first film when forming the contact hole.

### BACKGROUND

### Field of the Technology

The present disclosure relates to a method for forming a contact hole and a method for manufacturing a semiconductor device.

### Description of the Related Art

Japanese Patent Laid-Open No. 2014-123770 describes a photoelectric conversion apparatus including a charge holding portion covered with a light shielding film. Japanese Patent Laid-Open No. 2023-65467 describes a photoelectric conversion apparatus including a charge holding portion covered with a light shielding film and a photoelectric conversion apparatus including a photoelectric conversion portion covered with a light shielding film and capable of focus detection.

Processes for manufacturing semiconductor devices have been increasingly miniaturized. In a process involving a light shielding film described in Japanese Patent Laid-Open No. 2014-123770 or Japanese Patent Laid-Open No. 2023-65467, if the flatness of an insulating film before the light shielding film is formed or the flatness of an insulating film after the light shielding film is formed is low, a photoresist will be formed on a surface with irregularities. The fine unevenness on the upper surface of the photoresist hinders formation of a fine resist pattern, thereby making it difficult to increase the accuracy of forming a desired pattern.

### SUMMARY

According to an aspect of the present disclosure, a method for forming a contact hole includes forming a light shielding film on a substrate, forming a first film having a flat upper surface by applying a precursor on the substrate in such a manner that an application amount of the precursor is smaller on the light shielding film than on another portion, and patterning the first film when forming the contact hole.

Features of the present disclosure will become apparent from the following description of embodiments with reference to the attached drawings. The following description of embodiments is described by way of example.

### BRIEF DESCRIPTION OF THE DRAWINGS

FIG. 1 is an outline view illustrating the configuration of a planarization apparatus.

FIGS. 2A, 2B, and 2C are schematic views illustrating planarization processing.

FIGS. 3A and 3B are schematic views illustrating a method for manufacturing a semiconductor device according to a first embodiment.

FIGS. 4A to 4F are schematic views illustrating the method for manufacturing the semiconductor device according to the first embodiment.

FIGS. 5A to 5H are schematic views illustrating a method for manufacturing a semiconductor device according to a second embodiment.

FIGS. 6A to 6H are schematic views illustrating a method for manufacturing a semiconductor device according to a third embodiment.

FIGS. 7A to 7I are schematic views illustrating the method for manufacturing the semiconductor device according to the third embodiment.

FIGS. 8A, 8B, and 8C are schematic views each illustrating a semiconductor device according to a fourth embodiment.

FIGS. 9A, 9B, and 9C are schematic views each illustrating an application example of a semiconductor device according to a fifth embodiment.

### DESCRIPTION OF THE EMBODIMENTS

In the following description, each of embodiments will be described with reference to the drawings. However, the embodiments that will be described below are not intended to limit the disclosure set forth in the claims. A plurality of features will be described in the embodiments, but not all of the plurality of features are necessarily essential to the disclosure, and the plurality of features may be combined in any manner. Further, the same or similar configurations may be identified by the same reference numerals in the attached drawings, and duplicate descriptions may be omitted.

In the following description, the embodiments of the present disclosure will be described in detail with reference to the drawings. In the following description, terms indicating particular directions or positions (for example, “upper”, “lower”, “right”, “left”, and other terms including these terms) will be used as needed. The use of these terms is intended to facilitate the understanding of the embodiments with reference to the drawings, and the technical scope of the present disclosure shall not be limited by the meanings of these terms.

As will be used herein, a planar view will refer to a view from a direction perpendicular to an upper surface of a semiconductor substrate. Further, a cross-sectional view will refer to a section in a direction perpendicular to the upper surface of the semiconductor substrate. If the upper surface of the semiconductor substrate is a rough surface when being viewed microscopically, the planar view will be defined based on the upper surface of the semiconductor substrate when being viewed macroscopically. The upper surface of the semiconductor substrate will be defined to be a surface on which an element formed on the semiconductor substrate such as a gate of a transistor is mounted or a surface including a connection portion with a contact plug.

Further, expressions such as “A or B”, “at least one of A and B”, “at least one of A and/or B”, and “one or more of A and/or B” include all possible combinations of the listed items unless specifically explicitly defined. In other words, these expressions will be understood to disclose all of the following cases: a case where at least one A is included, a case where at least one B is included, and a case where at least one A and at least one B are both included. The same similarly applies to combinations of three or more elements.

### First Embodiment

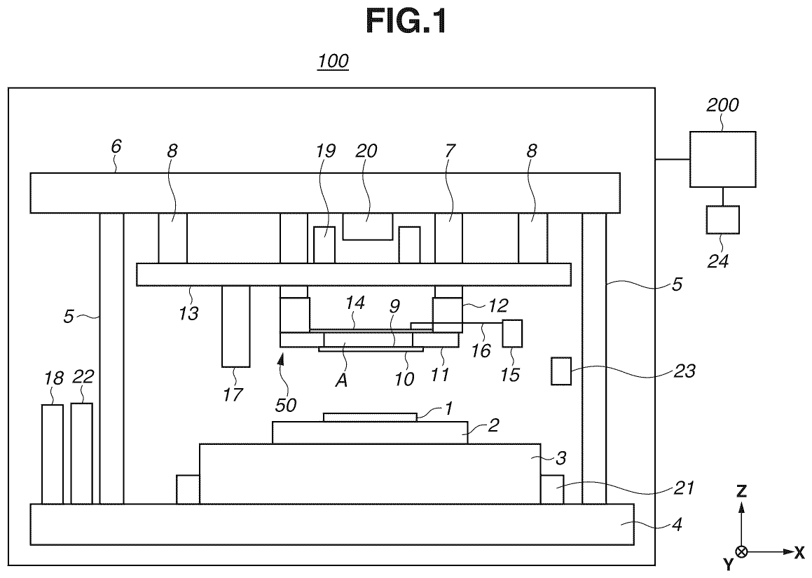

FIG. 1 is an outline view illustrating the configuration of a planarization apparatus 100 according to the present embodiment. Directions will be indicated in an XYZ coordinate system where a horizontal surface is defined as an XY plane. Generally, a substrate 1, which is a processing target, is placed on a substrate stage 3 in such a manner that the surface thereof extends in parallel to the horizontal surface (the XY plane). Therefore, hereinafter, directions orthogonal to each other in a plane extending along the surface of the substrate 1 will be defined as an X-axis and a Y-axis, and a direction perpendicular to the X-axis and the Y-axis will be defined as a Z-axis. Further, hereinafter, directions parallel to the X-axis, the Y-axis, and the Z-axis of the XYZ coordinate system will be referred to as an X-direction, a Y-direction, and a Z-direction, respectively, and a rotational direction around the X-axis, a rotational direction around the Y-axis, and a rotational direction around the Z-axis will be referred to as a θX-direction, a θY-direction, and a θZ-direction, respectively. As will be described below, the substrate 1 is a member to which a semiconductor process is applicable, such as a semiconductor wafer, a semiconductor wafer with a wiring structure formed thereon, a glass substrate with an element formed thereon, and a metallic substrate.

Underlying patterns on substrates have an uneven profile derived from a pattern formed in the previous process. Especially, the recent trend toward multi-layered structures of memory elements has led to emergence of process substrates having a level difference as large as approximately 100 nanometers (nm). A level difference due to a moderate undulation of a whole substrate can be corrected by a focus tracking function of a scan exposure apparatus used in a photolithographic process. However, fine unevenness with such a small pitch that it is undesirably contained within an exposure slit area of the exposure apparatus may fall outside the depth of focus (DOF) of the exposure apparatus. Conventionally, methods for forming a planarization layer or applying planarization processing, such as Spin On Carbon (SOC) and Chemical Mechanical Polishing (CMP), have been used as methods for planarizing the underlying patterns of the substrates. However, there lies such a disadvantage that a sufficient planarization performance cannot be acquired by the conventional techniques. For example, the manufacturing process has advanced to new technology nodes such as 22 nm, 16 nm, 14 nm, and 10 nm. Even though planarization layers sufficient for practical use have been acquired for nodes one generation ago, these planarization layers may be unable to stand practical use for nodes after that. For example, there may be a case where the surface unevenness of planarization layers that have been acceptable at the previous nodes is no longer tolerable at the next-generation nodes. Further, while CMP involves high process costs and is applicable to only limited process steps, the unevenness difference on the underlying layers due to the multi-layered structures is expected to become further significant in the future.

To solve this disadvantage, a planarization apparatus that planarizes a substrate using an imprinting technique has been studied. The planarization apparatus planarizes a local region in the substrate surface or the entire surface of the substrate by bringing a planarization surface of a member or an unpatterned member (a planar template) into contact with a composition in an uncured state that is supplied to the substrate in advance. After that, the composition is cured with the composition and the planar template in contact with each other, and the planar template is separated from the cured composition.

The planarization layer is formed on the substrate as a result. This planarization apparatus is not affected by the unevenness of the patterned surface of the substrate in contrast to a commonly employed planarization method using an SOC sacrifice film, and therefore is expected to improve the accuracy of the planarization compared with the existing method.

The planarization apparatus 100 illustrated in FIG. 1 can be embodied by a shaping apparatus that shapes a composition on the substrate 1 using a plate 9, which is a pressing member. The planarization apparatus 100 forms a planarization layer using a material on the substrate 1 by curing the composition with the material on the substrate 1 and the plate 9 in contact with each other, and separating the plate 9 from the cured composition.

The substrate 1 is a semiconductor, insulator, or metal substrate, and the shape of the substrate can be a circle like a silicon wafer or a quartz wafer, or a square or rectangle like a (mother) glass for a flat panel display (FPD). The material of the substrate 1 can be a single-crystalline silicon wafer, but is not limited thereto. The material of the substrate 1 can be an elemental semiconductor or a compound semiconductor such as silicon, germanium, diamond, silicon carbide, silicon-germanium, gallium nitride, gallium arsenide, indium arsenide, or cadmium telluride. Alternatively, the material of the substrate 1 can be an inorganic insulator such as silicon oxide, silicon nitride, aluminum oxide, or aluminum nitride. Alternatively, the material of the substrate 1 can be an organic insulator like polyimide, polyamide, or polycarbonate. Alternatively, the substrate 1 may be made of aluminum, a titanium-tungsten alloy, an aluminum-silicon alloy, or an aluminum-copper-silicon alloy. In other words, the substrate 1 can be made of one or a plurality of materials arbitrarily selected from the above-listed materials and the like. At least one layer of a semiconductor, insulator, or metal film may be formed on the surface of the substrate 1, and the surface of the film can be a flat surface or a surface with unevenness formed thereon.

Further, usable substrates include a substrate improved in adhesion to the composition by forming an adhesion layer on the surface of the substrate 1 by a surface treatment, such as a silane coupling treatment, a silazane treatment, or organic thin film deposition. The substrate 1 typically has a circular shape of 300 millimeters (mm) in diameter, but is not limited thereto.

The plate 9 can be made of a light transmissive material in consideration of a light irradiation process. Examples of types of such a material include a light transmissive inorganic material such as glass or quartz, or a light transmissive organic material such as polymethyl methacrylate (PMMA), polycarbonate resin, or the like. The plate 9 may be either a rigid plate or a flexible film. Then, the surface of the plate 9 in contact with the composition is flat. The plate 9 can have a circular shape larger than 300 mm and smaller than 500 mm in diameter, but is not limited thereto. Further, the thickness of the plate 9 can be 0.25 mm or more and 2 mm or less, but is not limited thereto. In a case where the composition is a thermosetting material instead of a photo-curable material, the plate 9 can be non-transparent and can be made of any material having the above-described properties.

The composition is a precursor that, upon curing, forms at least a part of a planarization film, and is a curable composition that is curable in reaction to light or thermal energy. The curable composition curable in reaction to light or thermal energy can be a photo-curable composition curable by being irradiated with light, a thermosetting composition curable by being heated, or photothermally curable composition curable in reaction to light and thermal energy. Examples of the photo-curable composition include ultraviolet (UV) curable liquid. As the UV curable liquid, typically, a monomer such as acrylate or methacrylate can be used. The curable composition may also be referred to as a moldable material. Hereinafter, the moldable material may also be referred to as a “material”simply.

The planarization apparatus 100 includes a substrate chuck 2, a substrate stage 3, a base platen 4, columns 5, a top plate 6, a guide bar 7, columns 8, a plate chuck 11, a head 12, and an alignment shelf 13, as illustrated in FIG. 1. The planarization apparatus 100 further includes a pressure adjustment unit 15, a supply unit 17, a substrate conveyance unit 18, an alignment scope 19, a light source 20, a stage drive unit 21, a plate conveyance unit 22, a cleaning unit 23, an input unit 24, and a control unit 200. The substrate chuck 2 and the substrate stage 3 can move the substrate 1 while holding it. Further, the plate chuck 11 and the head 12 can move the plate 9 while holding it.

The substrate 1 is transported from outside the planarization apparatus 100 by the substrate conveyance unit 18 including a conveyance hand or the like, and is held by the substrate chuck 2. The substrate stage 3 is supported by the base platen 4, and is driven in the X-direction and the Y-direction to position the substrate 1 held by the substrate chuck 2 at a predetermined position. The stage drive unit 21 includes, for example, a linear motor or an air cylinder, and drives the substrate stage 3 at least in the X-direction and the Y-direction, but may have a function of driving the substrate stage 3 in directions of two or more axes (for example, six axial directions). Further, the stage drive unit 21 includes a rotation mechanism, and can rotationally drive the substrate chuck 2 or the substrate stage 3 in the θZ-direction.

The plate 9 serving as the pressing member is transported from outside the planarization apparatus 100 by the plate conveyance unit 22 including a conveyance hand or the like, and is held by the plate chuck 11. The plate 9 has, for example, a circular or quadrilateral outer shape, and has a first surface including a flat surface 10, which is to be in contact with the material placed on the substrate 1, and a second surface opposite from the first surface. In the present embodiment, the flat surface 10 has a size equal to or larger than the substrate 1. The plate chuck 11 is supported by the head 12, and can have a function of correcting the position of the plate 9 in the θZ-direction (an inclination around the Z-axis). Each of the plate chuck 11 and the head 12 includes an opening that permits light (an ultraviolet ray) emitted from the light source 20 via a collimator lens to pass therethrough. The plate chuck 11 functions as a holding unit that mechanically holds the plate 9. For example, the plate chuck 11 holds the plate 9 by attracting the second surface of the plate 9 with this second surface facing upward. Further, the head 12 mechanically holds the plate chuck 11. The plate chuck 11 and the head 12 constitute a formation unit 50 that performs processing for forming a planarization film. The head 12 includes a drive mechanism (not illustrated) for positionally determining a distance between the substrate 1 and the plate 9 when the plate 9 is brought into and out of contact with the material on the substrate 1, and moves the plate 9 in the Z-direction. The drive mechanism of the head 12 can include an actuator such as a linear motor, an air cylinder, or a voice coil motor. Further, a load cell for measuring the pressing force (imprinting force) of the plate 9 against the material on the substrate 1 can be disposed on the plate chuck 11 or the head 12. A plate deformation mechanism (a plate deformation unit) first includes a closing member 14 for closing a space region A, which is defined by an inner space surrounded by a space present inside the plate chuck 11 and the plate 9, into a closed space. Further, the plate deformation mechanism includes the pressure adjustment unit 15 disposed outside the plate chuck 11 and configured to adjust the pressure in the space region A. The closing member 14 is made of a light transmissive flat plate member such as quartz glass, and includes a connection port (not illustrated) of a pipe 16 connected to the pressure adjustment unit 15 in a part of the closing member 14. When the pressure adjustment unit 15 increases the pressure in the space region A, the amount of deformation of the plate 9 protruding toward the substrate side can be increased. On the other hand, when the pressure adjustment unit 15 reduces the pressure in the space region A, the amount of deformation of the plate 9 into a convex shape can be reduced. The columns 5 supporting the top plate 6 are disposed on the base platen 4. The guide bar 7 is suspended from the top plate 6, extends through the alignment shelf 13, and is fixed to the head 12. The alignment shelf 13 is suspended from the top plate 6 via the columns 8. The guide bar 7 extends through the alignment shelf 13. Further, for example, a height measurement system (not illustrated) for measuring the height (the degree of flatness) of the substrate 1 held by the substrate chuck 2 using an oblique incidence image displacement method is disposed on the alignment shelf 13.

The alignment scope 19 includes an optical system and an imaging system for observing a reference mark provided on the substrate stage 3 and an alignment mark provided on the plate 9. However, in a case where the alignment mark is not provided on the plate 9, the alignment scope 19 may be omitted. The alignment scope 19 is used in alignment that measures the relative position between the reference mark provided on the substrate stage 3 and the alignment mark provided on the plate 9 and corrects a positional misalignment therebetween.

The supply unit 17 includes a dispenser equipped with a discharge port (a nozzle) that discharges the material in an uncured state to the substrate 1, and supplies (applies) the material onto the substrate 1. The supply unit 17 employs, for example, a piezo jet method or a micro solenoid method, and can supply the material by an extremely small volume of approximately 1 picoliter (pL) onto the substrate 1 during scan driving of the substrate stage 3. The number of discharge ports in the supply unit 17 is not limited, and may be one (a single nozzle) or may be plural (for example, 100 or more). A linear nozzle array in one row or in a plurality of rows may be formed by a plurality of nozzles. Especially, a dispenser based on a method known as an inkjet head can apply the material in the form of liquid to the substrate 1 as an extremely small droplet, thereby being effectively usable. Especially, a piezo inkjet head including at least one discharge energy generator realized by a piezoelectric element for each discharge port can change the volume of the droplet to discharge, thereby being further effectively usable.

The cleaning unit 23 cleans the plate 9 with the plate 9 held by the plate chuck 11. In the present embodiment, the cleaning unit 23 removes the material attached to the plate 9, especially, the flat surface 10, by separating the plate 9 from the cured material on the substrate 1. The cleaning unit 23 may, for example, by wipe off the material attached to the plate 9, or may remove the material attached to the plate 9 using UV irradiation, static electricity removal, wet cleaning, dry plasma cleaning, or the like.

The control unit 200 is configured by a computer device including a central processing unit (CPU) and a memory, and controls the entire planarization apparatus 100. The control unit 200 functions as a processing unit that performs planarization processing by comprehensively controlling each unit of the planarization apparatus 100. Here, the planarization processing refers to processing for planarizing the material by bringing the flat surface 10 of the plate 9 into contact with the material on the substrate 1 and causing the flat surface 10 to conform to the surface profile of the substrate 1. Generally, the planarization processing is performed lot by lot, i.e., for each of a plurality of substrates included in a single lot.

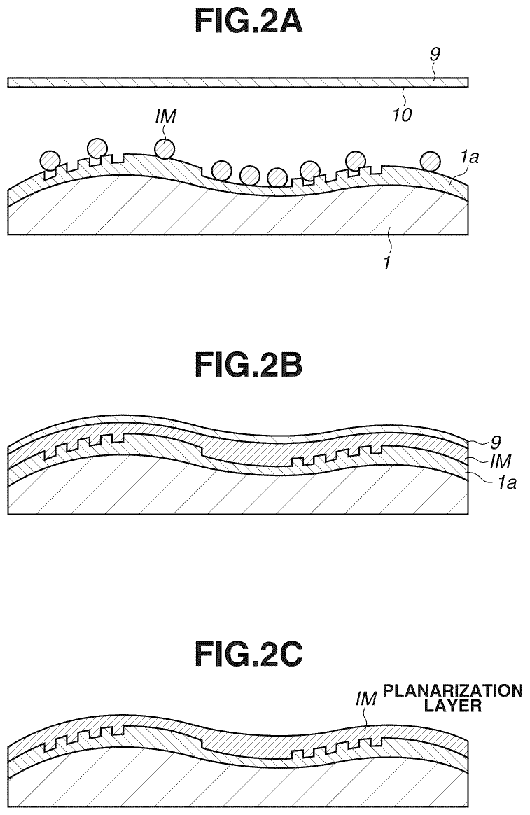

Next, the planarization processing will be described with reference to FIGS. 2A, 2B, and 2C. First, a material IM is supplied by the supply unit 17 to the substrate 1 with an underlying pattern 1a formed thereon. FIG. 2A illustrates a state after the material IM is placed on the substrate 1 and before the plate 9 is brought into contact with the substrate 1 with the underlying pattern 1a formed thereon. Next, as illustrated in FIG. 2B, the material IM on the substrate 1 and the flat surface 10 of the plate 9 are brought into contact with each other. The plate 9 presses the material IM, and the material IM spreads over the entire surface of the substrate 1 thereby. FIG. 2B illustrates a state in which the entire surface of the flat surface 10 of the plate 9 is in contact with the material IM on the substrate 1, and the flat surface 10 of the plate 9 conforms to the surface profile of the substrate 1. Then, in the state illustrated in FIG. 2B, the material IM on the substrate 1 is irradiated with the light from the light source 20 via the plate 9, and the material IM is cured accordingly. After that, the plate 9 is separated from the cured material IM on the substrate 1. As a result, the material IM is formed into a layer (a planarization layer) uniform in thickness over the entire surface of the substrate 1. FIG. 2C illustrates a state in which the planarization layer using the material IM is formed on the substrate 1. Hereinafter, contact (adhesion) and separation between the flat surface 10 of the plate 9 and the material IM on the substrate 1 will be simply referred to as contact (adhesion) and separation between the plate 9 and the material IM on the substrate 1, respectively. Further, hereinafter, the material IM will also be referred to as a precursor when being in a state supplied to the substrate 1, and will also be referred to as a film after being cured. A precursor corresponding to a first material IM1 and a film corresponding to the first material IM1 may be referred to as a first precursor and a first film, respectively. A precursor corresponding to a second material IM2 and a film corresponding to the second material IM2 may be referred to as a second precursor and a second film, respectively.

Next, a method for manufacturing an article (a semiconductor device, a liquid crystal display device, a color filter, a micro electro-mechanical system (MEMS), or the like) using this planarization apparatus 100 will be described. This manufacturing method includes a process of planarizing a composition disposed on a substrate (a wafer, a glass substrate, or the like) by bringing the composition into contact with a mold, a process of curing the composition, and a process of separating the composition and the mold from each other by using the above-described planarization apparatus 100. As a result, a planarization film is formed on the substrate. Then, the article is manufactured by performing processing such as formation of a pattern (patterning) using a lithography apparatus on the substrate with the planarization film formed thereon, and applying another known processing process to the processed substrate. Examples of the other known process include etching, a removal of a resist, dicing, bonding, and packaging. According to the present manufacturing method, it is possible to produce articles of higher quality than those produced by conventional methods.

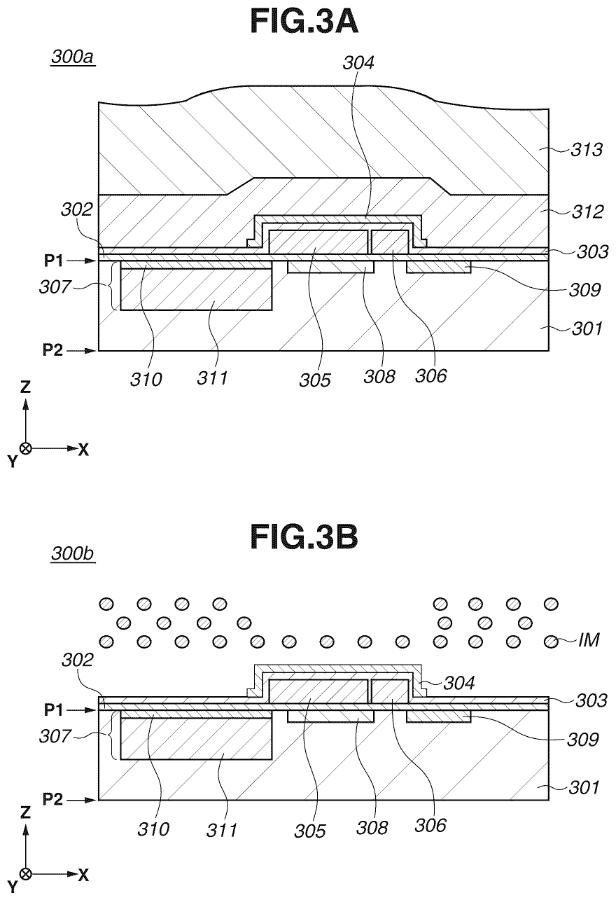

In the following description, the present manufacturing method will be described citing an example in the case of a semiconductor device as a specific article. FIGS. 3A and 3B are schematic views illustrating the method for manufacturing the semiconductor device according to the present embodiment, and illustrate processes for forming a contact hole. A semiconductor device 300a and a semiconductor device 300b each include a semiconductor substrate 301, a gate insulating film 302, a first insulating film 303, a light shielding film 304, a first transfer gate electrode 305, and a second transfer gate electrode 306. A surface P1 is an upper surface of the semiconductor substrate 301, and a surface P2 is a lower surface of the semiconductor substrate 301. Further, the semiconductor substrate 301 includes a photoelectric conversion portion 307, a charge holding portion 308, and a floating diffusion portion 309. The photoelectric conversion portion 307 includes a surface protection portion 310 and a charge accumulation portion 311. Furthermore, the semiconductor device 300a illustrated in FIG. 3A further includes a second insulating film 312 and a first photoresist film 313. In FIG. 3A, the gate insulating film 302, the first insulating film 303, the light shielding film 304, the second insulating film 312, and the first photoresist film 313 are disposed on the surface P1 of the semiconductor substrate 301 in this order. In other words, the gate insulating film 302 is disposed between the first photoresist film 313 and the surface P1 of the semiconductor substrate 301. In FIG. 3B, the gate insulating film 302, the first insulating film 303, and the light shielding film 304 are disposed on the surface P1 of the semiconductor substrate 301 in this order. In other words, the gate insulating film 302 is disposed between the light shielding film 304 and the surface P1 of the semiconductor substrate 301.

The photoelectric conversion portion 307 generates a charge according to incident light. The charge holding portion 308 accumulates and holds the charge transferred from the photoelectric conversion portion 307. The floating diffusion portion 309 receives the charge transferred from the charge holding portion 308. A first transfer transistor including the first transfer gate electrode 305 transfers the charge from the photoelectric conversion portion 307 to the charge holding portion 308. A second transfer transistor including the second transfer gate electrode 306 transfers the charge from the charge holding portion 308 to the floating diffusion portion 309. The present embodiment will be described based on an example case where electrons in electron-hole pairs generated by the photoelectric conversion portion 307 due to the incident light are used as signal charges. When electrons are used as the signal charges, the charge holding portion 308, the floating diffusion portion 309, and the charge accumulation portion 311 are formed as N-type semiconductor regions, and the surface protection portion 310 is formed as a P-type semiconductor region. However, the signal charges are not limited to electrons, and holes may be used as the signal charges. When holes are used as the signal charges, the above-described conductivity type of each of the semiconductor regions is different.

The gate insulating film 302, the first insulating film 303, and the second insulating film 312 can be formed of a single layer of any insulator material such as silicon oxide, silicon oxynitride, silicon nitride, silicon carbide oxide, spin-on-glass (SOG), or a low dielectric material, or a plurality of layers of them. The light shielding film 304 can be made of, for example, a metal. The light shielding film 304 is composed of a metal material with high light shielding properties. For example, the light shielding film 304 can be made of a single metal material such as tungsten or aluminum. Alternatively, a layered film of aluminum and barrier metal (for example, titanium, cobalt, or nickel), a layered film of tungsten and barrier metal (for example, titanium, cobalt, or nickel), or the like can be used as the light shielding film 304.

FIG. 3A illustrates a state in which the first photoresist film 313 for forming a photoresist pattern for the contact hole is formed after the second insulating film 312 is formed on the semiconductor substrate 301. The first photoresist film 313 is formed so as to cover the upper surface of the second insulating film 312. At this time, a bump portion can be generated on the upper surface of the second insulating film 312 due to the light shielding film 304. Further, a bump portion can be generated on the upper surface of the first photoresist film 313 in accordance with the bump portion generated on the upper surface of the second insulating film 312. If the upper surface of the first photoresist film 313 has low flatness in this manner, it hinders image formation when the first photoresist film 313 is exposed to the light, making it difficult to form a fine photoresist pattern. Especially, using a short wavelength such as extreme ultraviolet (EUV) leads to a shallow depth of focus of the exposure apparatus, and therefore the flatness and evenness of the film thickness of the photoresist are important.

In light thereof, in the embodiment of the present disclosure, an application amount of the precursor (the material IM) in the form of liquid of a material usable as an etching mask in a subsequent process is determined in advance, and the predetermined amount is applied so that a smaller amount is deposited on the upper portion of the light shielding film 304 and a larger amount is deposited on the other portions, as illustrated in FIG. 3B. The precursor in the form of liquid can be a precursor of energy-curable resin or a precursor of SOC. Then, this liquid is cured with the flat surface 10 of the plate 9 pressed against the liquid as necessary.

After the curing, the photoresist film is formed. Since the liquid is applied between a plurality of light shielding films 304 before the photoresist film is formed, the degree of flatness is further improved on the surface of the photoresist film formed after that compared with the state illustrated in FIG. 3A, allowing the photoresist film to be sufficiently exposed to the light even with the shallow depth of focus. The resist pattern is formed by developing the photoresist film exposed to light in this manner.

When the uncured material is applied, the inkjet head with the piezoelectric element mounted thereon as the discharge actuator is used between the plurality of light shielding films 304 formed in advance. More specifically, this method can be realized by injecting a droplet on the upper portion of the light shielding film 304 N times (N is a natural number) per unit area, and injecting a droplet on the planarization surface of the first insulating film 303 other than that (between the plurality of light shielding films 304) N+1 times or more per unit area. Such a number of times of droplet application can be determined depending on the formed pattern of the light shielding film 304. More specifically, the droplets are applied while the relative position between the discharge port and the substrate is changed according to a drawing map determining the number (or the amount) of droplets applied onto the substrate and the application position in the upper surface based on pattern data of a resist mask for forming the light shielding film 304.

Because the space between the plurality of light shielding films 304 is filled with liquid in this manner, the resist film formed after that has a planarized surface. A composition curable in reaction to light energy (the precursor of the cured film) can be used as the liquid used at this time.

On the other hand, a resist in which some portion becomes soluble to developer in reaction to light energy, a so-called positive resist can be used as the resist film. The apparatus for exposing the resist film to light can be an EUV exposure apparatus, and can be an apparatus having a numerical aperture NA of 0.33 or more and 0.75 or less. For example, the numerical aperture NA can be 0.55. The numerical aperture NA may be a value greater than 0.55. The numerical aperture NA may be a value greater than 0.75. Further, the exposure apparatus may be an argon fluoride (ArF) immersion exposure apparatus, an ArF dry exposure apparatus, or a krypton fluoride (KrF) exposure apparatus.

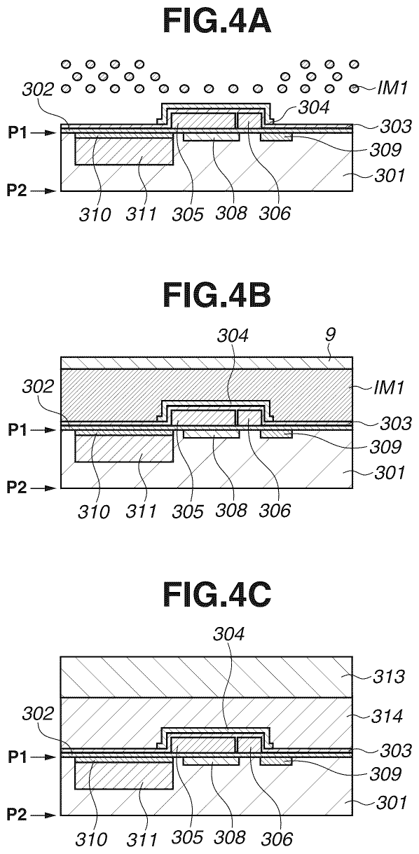

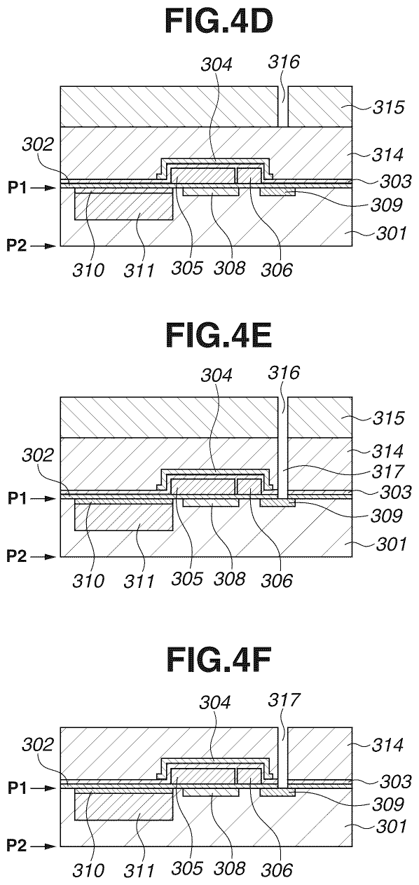

Next, the method for manufacturing the semiconductor device according to the present embodiment will be described. FIGS. 4A to 4F are schematic views illustrating the method for manufacturing the semiconductor device according to the first embodiment. The manufacturing method illustrated in FIGS. 4A to 4F is a method in which the planarization method illustrated in FIGS. 1, 2A, 2B, and 2C is applied to the manufacturing of the contact hole illustrated in FIGS. 3A and 3B.

In FIG. 4A, a first material IM1 of the cured film is applied after the process of forming the light shielding film 304 similarly to FIG. 3B. The application amount of the first material IM1 is adjusted along the profile of the upper surface of the first insulating film 303. At this time, the first material IM1 is supplied in such a manner that the application amount thereof is smaller on the upper portion of the light shielding film 304 than on the flat upper surface of the first insulating film 303 around it (between the plurality of light shielding films 304). To achieve this, the application amount can be controlled by, for example, changing the number of droplets or the size of droplets of the precursor (the liquid) of the first material IM1 discharged by the inkjet method.

Next, the upper surface of the first material IM1 is planarized by bringing the plate 9 into contact with the first material IM1 as necessary, as illustrated in FIG. 4B. Then, the first material IM1 is irradiated with the light via the plate 9. The first material IM1 is cured by being irradiated with the light. After that, the plate 9 is separated from the cured first material IM1 on the semiconductor substrate 301. Due to this planarization processing, a first film 314 is formed with the upper surface thereof achieving excellent flatness. Then, the first material IM1 can be, for example, a precursor of energy-curable resin or a precursor of SOC as described above.

As illustrated in FIG. 4C, the first photoresist film 313 is formed on the upper surface of the first film 314. Since the first photoresist film 313 is formed on the first film 314, which has excellent flatness, the upper surface of the first photoresist film 313 also achieves excellent flatness. The first photoresist film 313 is exposed to the light according to any pattern. At this time, the exposure can be EUV exposure. Development of the first photoresist film 313 subjected to the EUV exposure makes the portion exposed to the light solvable to the developer, thereby forming the resist pattern. In this manner, a first resist pattern 315 is formed as illustrated in FIG. 4D. The first resist pattern 315 has a first opening 316. The first film 314 is exposed to outside due to the first opening 316.

A contact hole 317 is formed by removing a part of the first film 314, a part of the first insulating film 303, and a part of the gate insulating film 302 in the state illustrated in FIG. 4D. The contact hole 317 is formed so as to extend through the first film 314, the first insulating film 303, and the gate insulating film 302 to expose the floating diffusion portion 309 to outside. The contact hole 317 in communication with the first opening 316 is formed by conducting anisotropic etching on the first film 314 with a reactive ion etching apparatus using the first resist pattern 315 as a mask. If the first resist pattern 315 is highly resistant to the etching at the time of this etching, the first resist pattern 315 can remain as illustrated in FIG. 4E. In this case, the first resist pattern 315 is removed after the contact hole 317 is formed. In this manner, the structure having the contact hole 317 can be formed.

However, in a case where there is no large difference between the etching rates for the first resist pattern 315 and the first film 314, this leads to sequential removals of the first resist pattern 315 and the first film 314 at the position where the contact hole 317 is formed when the first film 314 is etched. This means that, when the contact hole 317 is formed by the etching, the first resist pattern 315 and the first film 314 at the position where the contact hole 317 is formed are eliminated except for residues as illustrated in FIG. 4F. The residues of the first resist pattern 315 and the first film 314 may be removed if necessary.

After that, a conductor film is formed so as to fill the contact hole 317, and the excessive conductor film is removed. As a result, a conductor portion embedded in the contact hole 317 is formed. Then, the conductor may have a structure constituted by a plurality of layers of barrier metal such as transition metal (e.g., titanium (Ti) or tantalum (Ta)) or a transition metal compound (e.g., titanium nitride (TiN) or tantalum nitride (TaN)), and embedded metal such as copper (Cu). The embedding process can be performed by employing a known technique, such as film deposition by chemical vapor deposition (CVD), sputtering, plating, or the like, and polishing of the conductor by CMP.

According to the above-detailed method, the present embodiment can increase the flatness of the upper surface of the photoresist and the evenness of the film thickness of the photoresist before the exposure to the light, thereby improving the accuracy of forming the resist pattern. In other words, the present embodiment can improve the accuracy of forming the contact hole.

Then, for example, the flatness of the upper surface of the photoresist expected for EUV exposure is <10 nm. The planarization method according to the present embodiment facilitates satisfying the flatness of the upper surface of the photoresist. Further, for EUV exposure, the present embodiment can be effectively used when the numerical aperture NA is greater than 0.33, especially greater than 0.55.

In this manner, the method for forming the contact hole according to the present embodiment allows the contact hole to be accurately formed.

### Second Embodiment

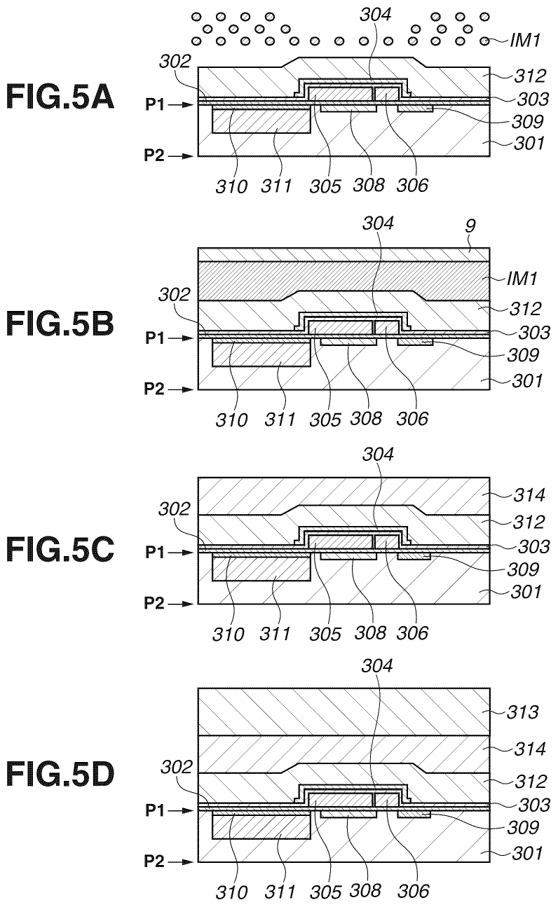

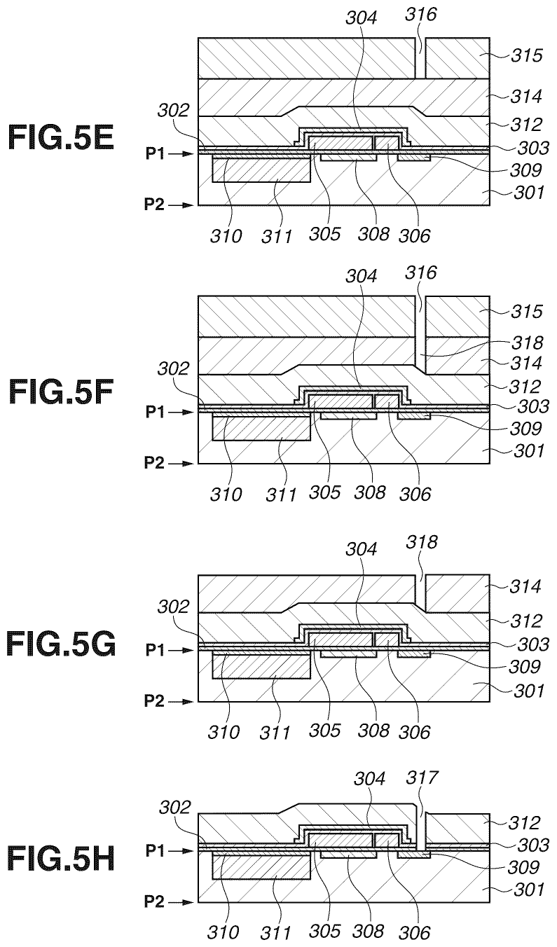

A method for manufacturing a semiconductor device according to the present embodiment will be described. FIGS. 5A to 5H are schematic views illustrating the method for manufacturing the semiconductor device according to the second embodiment. The manufacturing method illustrated in FIGS. 5A to 5H forms a contact hole in an insulating layer different from the first film compared with the manufacturing method illustrated in FIGS. 4A to 4F. In the following description, the present embodiment will be described, omitting the detailed descriptions of configurations and processes similar to FIGS. 4A to 4F.

In FIG. 5A, the first material IM1 of the cured film is applied after the process of forming the second insulating film 312 on the light shielding film 304. In FIG. 5A, a bump portion is generated in accordance with the light shielding film 304 on the upper surface of the second insulating film 312, similarly to FIG. 3A. In other words, a part of the second insulating film 312 disposed on the light shielding film 304 forms the bump portion. The application amount of the first material IM1 is adjusted along the profile of the upper surface of the second insulating film 312. At this time, the first material IM1 is supplied in such a manner that the application amount thereof is smaller on a part of the second insulating film 312 forming the bump portion than on the flat upper surface around it. To achieve this, the application amount can be controlled by, for example, changing the number of droplets or the size of droplets of the precursor (the liquid) of the first material IM1 discharged by the inkjet method.

The upper surface of the first material IM1 is planarized by bringing the flat surface of the plate 9 into contact with the first material IM1 as necessary, as illustrated in FIG. 5B. Then, the first material IM1 is irradiated with the light via the plate 9, thereby being cured. This process is similar to the process illustrated in FIG. 4B. Further, after the first film 314 is formed by curing the first material IM1, the plate 9 is separated as illustrated in FIG. 5C.

After the plate 9 is separated, the first photoresist film 313 is formed on the planarized upper surface of the first film 314 as illustrated in FIG. 5D. Then, a latent image is formed on the first photoresist film 313 by exposing the first photoresist film 313 to the light according to any pattern, and then, the latent image is developed and subjected to post bake.

In this manner, the first resist pattern 315 is formed as illustrated in FIG. 5E. The first resist pattern 315 has the first opening 316. A second opening 318 is formed in the first film 314 by removing a part of the first film 314 in the state illustrated in FIG. 5E. The second opening 318 in communication with the first opening 316 is formed by conducting anisotropic etching on the first film 314 with a reactive ion etching apparatus using the first resist pattern 315 as a mask. If the first resist pattern 315 is highly resistant to the etching at the time of this etching, the first resist pattern 315 can remain as illustrated in FIG. 5F. In this case, the first resist pattern 315 is removed after the second opening 318 is formed.

However, in a case where there is no large difference between the etching rates for the first resist pattern 315 and the first film 314, this leads to sequential removals of the first resist pattern 315 and the first film 314 at the position where the second opening 318 is formed when the first film 314 is etched. This means that, when the second opening 318 is formed by the etching, the first resist pattern 315 and the first film 314 at the position where the second opening 318 is formed are eliminated except for residues as illustrated in FIG. 5G. The residues of the first resist pattern 315 and the first film 314 may be removed as necessary.

The contact hole 317 is formed by removing a part of the second insulating film 312, a part of the first insulating film 303, and a part of the gate insulating film 302 in the state illustrated in FIG. 5G. The contact hole 317 is formed so as to extend through the second insulating film 312, the first insulating film 303, and the gate insulating film 302 to expose the floating diffusion portion 309 to outside. The contact hole 317 in communication with the second opening 318 is formed by conducting anisotropic etching on the second insulating film 312 with a reactive ion etching apparatus using the first film 314 as a mask. Then, in a case where there is no large difference between the etching rates for the first film 314 and the second insulating film 312, this leads to sequential removals of the first film 314 and the second insulating film 312 at the position where the contact hole 317 is formed when the second insulating film 312 is etched. This means that, when the contact hole 317 is formed by the etching, the first film 314 and the second insulating film 312 at the position where the contact hole 317 is formed are eliminated except for residues as illustrated in FIG. 5H. The residues of the first film 314 and the second insulating film 312 may be removed as necessary.

However, if the first film 314 is highly resistant to the etching, the first film 314 can remain. In this case, the first film 314 is removed after the contact hole 317 is formed.

After that, a conductor portion that fills the contact hole 317 can be formed by embedding a conductor in the contact hole 317 similarly to the above-described method.

According to the method, the present embodiment can increase the flatness of the upper surface of the photoresist, thereby improving the accuracy of forming the resist pattern. In other words, the present embodiment can improve the accuracy of forming the contact hole. In this manner, the method for forming the contact hole according to the present embodiment allows the contact hole to be accurately formed.

### Third Embodiment

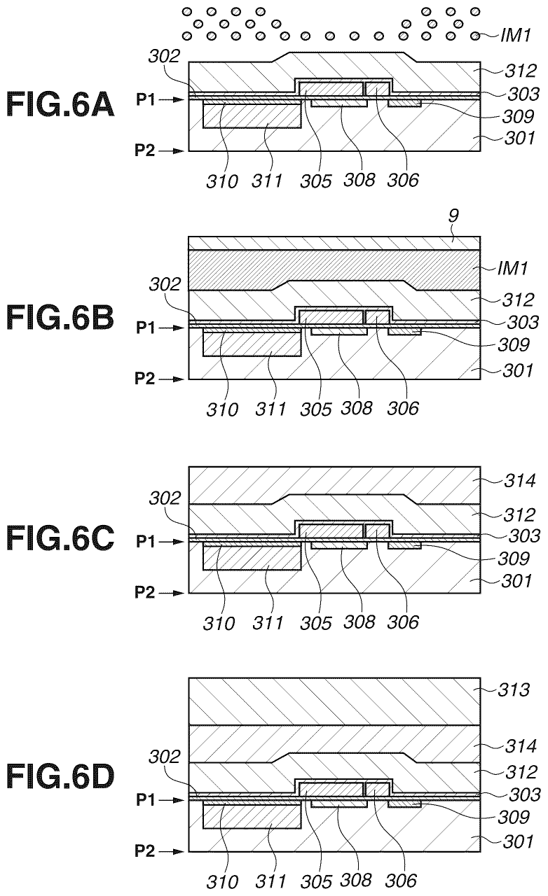

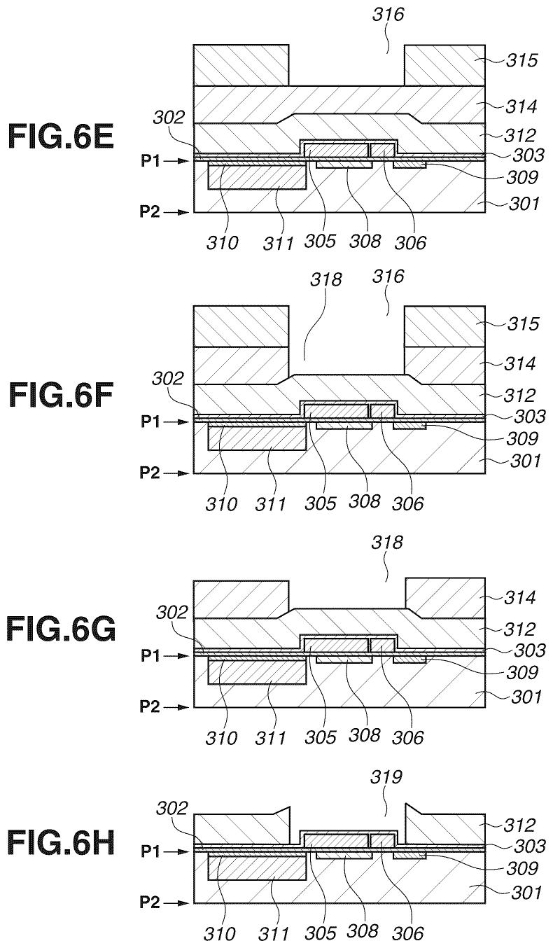

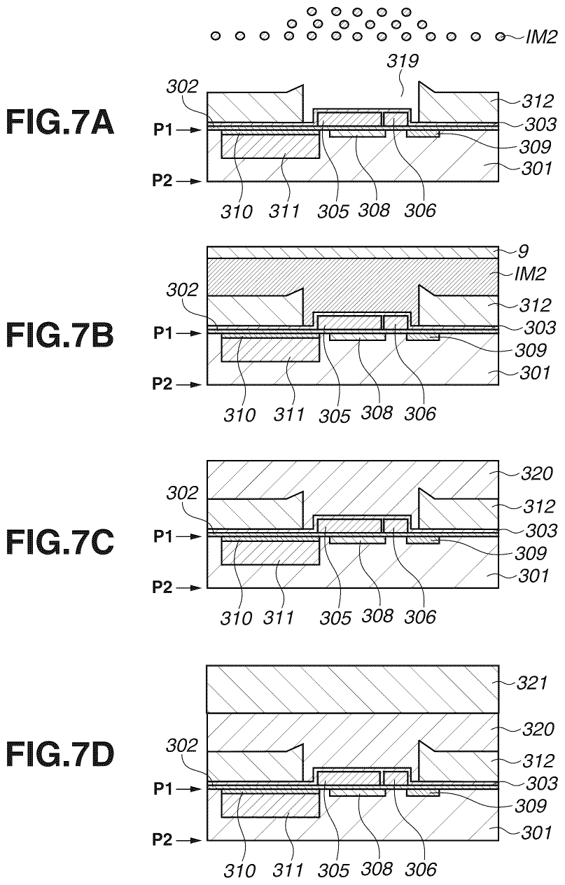

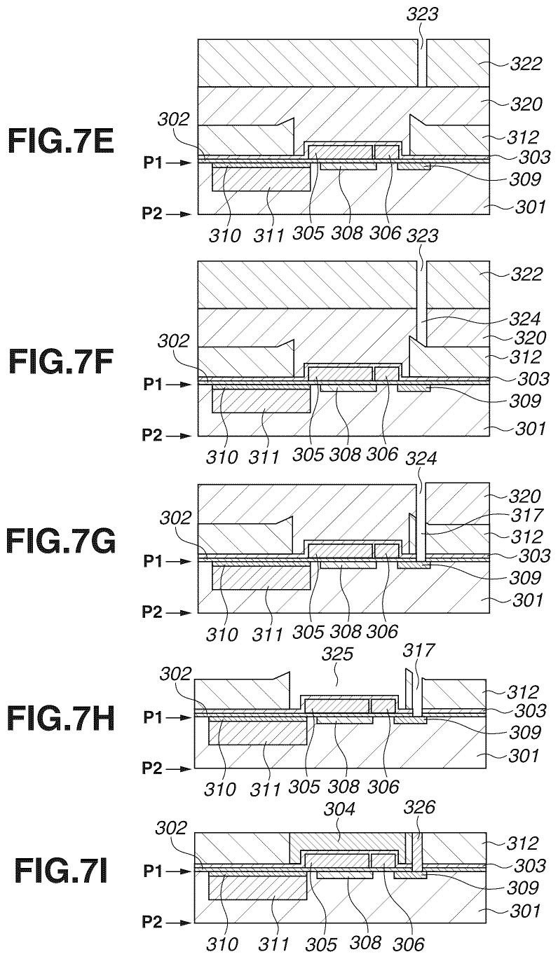

A method for manufacturing a semiconductor device according to the present embodiment will be described. FIGS. 6A to 6H and 7A to 7I are schematic views illustrating the method for manufacturing the semiconductor device according to the third embodiment. The manufacturing method illustrated in FIGS. 6A to 6H and 7A to 7I is different from the manufacturing method illustrated in FIGS. 5A to 5H in terms of the timing of forming the light shielding film. In the following description, the present embodiment will be described, omitting the detailed descriptions of configurations and processes similar to FIGS. 5A to 5H.

In the processes illustrated in FIGS. 6A to 6D, the light shielding film 304 is not formed. The processes illustrated in FIGS. 6A to 6D are similar to the processes illustrated in FIGS. 5A to 5D except that the semiconductor device is configured not to include the light shielding film 304.

In the state illustrated in FIG. 6D, a latent image is formed on the first photoresist film 313 by exposing the first photoresist film 313 to the light according to any pattern, and then, the latent image is developed and subjected to post bake.

In this manner, the first resist pattern 315 is formed as illustrated in FIG. 6E. The first resist pattern 315 has the first opening 316. The second opening 318 is formed in the first film 314 by removing a part of the first film 314 in the state illustrated in FIG. 6E. The second opening 318 in communication with the first opening 316 is formed by conducting anisotropic etching on the first film 314 with a reactive ion etching apparatus using the first resist pattern 315 as a mask. If the first resist pattern 315 is highly resistant to the etching at the time of this etching, the first resist pattern 315 can remain as illustrated in FIG. 6F. In this case, the first resist pattern 315 is removed after the second opening 318 is formed.

However, in a case where there is no large difference between the etching rates for the first resist pattern 315 and the first film 314, this leads to sequential removals of the first resist pattern 315 and the first film 314 at the position where the second opening 318 is formed when the first film 314 is etched. This means that, when the second opening 318 is formed by the etching, the first resist pattern 315 and the first film 314 at the position where the second opening 318 is formed are eliminated except for residues as illustrated in FIG. 6G. The residues of the first resist pattern 315 and the first film 314 may be removed as necessary.

In the present embodiment, the first opening 316 and the second opening 318 may be formed at positions at least partially overlapping the charge holding portion 308 in a planar view of the surface P1.

In the present embodiment, the first opening 316 and the second opening 318 may be formed at a position at least partially overlapping the first transfer gate electrode 305 in the planar view of the surface P1. In the present embodiment, the first opening 316 and the second opening 318 may be formed at a position at least partially overlapping the second transfer gate electrode 306 in the planar view of the surface P1.

A third opening 319 is formed by removing a part of the second insulating film 312 in the state illustrated in FIG. 6G. The third opening 319 is formed so as to extend through the second insulating film 312 to expose the first insulating film 303 to outside. The third opening 319 in communication with the second opening 318 is formed by conducting anisotropic etching on the second insulating film 312 with a reactive ion etching apparatus using the first film 314 as a mask. Then, in a case where there is no large difference lies between the etching rates for the first film 314 and the second insulating film 312, this leads to sequential removals of the first film 314 and the second insulating film 312 at the position where the third opening 319 is formed when the second insulating film 312 is etched. This means that, when the third opening 319 is formed by the etching, the first film 314 and the second insulating film 312 at the position where the third opening 319 is formed are eliminated except for residues as illustrated in FIG. 6H. The residues of the first film 314 and the second insulating film 312 may be removed as necessary.

However, if the first film 314 is highly resistant to the etching, the first film 314 can remain. In this case, the first film 314 is removed after the third opening 319 is formed.

In FIG. 7A, a second material IM2 of the cured film is applied after the process of forming the third opening 319 illustrated in FIG. 6H. The application amount of the second material IM2 is adjusted along the profile of the upper surface of the second insulating film 312. At this time, the second material IM2 is supplied in such a manner that the application amount thereof is larger in the third opening 319 than on the flat upper surface around it. To achieve this, the application amount can be controlled by, for example, changing the number of droplets or the size of droplets of the precursor (the liquid) of the second material IM2 discharged by the inkjet method.

The upper surface of the second material IM2 is planarized by bringing the flat surface of the plate 9 into contact with the second material IM2 as necessary, as illustrated in FIG. 7B. Then, the second material IM2 is irradiated with the light via the plate 9, thereby being cured. Further, after a second film 320 is formed by curing the second material IM2, the plate 9 is separated as illustrated in FIG. 7C.

After the plate 9 is separated, a second photoresist film 321 is formed on the planarized upper surface of the second film 320 as illustrated in FIG. 7D. Then, a latent image is formed on the second photoresist film 321 by exposing the second photoresist film 321 to the light according to any pattern, and the latent image is developed and subjected to post bake.

In this manner, a second resist pattern 322 is formed as illustrated in FIG. 7E. The second resist pattern 322 has a fourth opening 323. A fifth opening 324 is formed in the second film 320 by removing a part of the second film 320 in the state illustrated in FIG. 7E. The fifth opening 324 in communication with the fourth opening 323 is formed by conducting anisotropic etching on the second film 320 with a reactive ion etching apparatus using the second resist pattern 322 as a mask. If the second resist pattern 322 is highly resistant to the etching at the time of this etching, the second resist pattern 322 can remain as illustrated in FIG. 7F. In this case, the second resist pattern 322 is removed after the fifth opening 324 is formed.

However, in a case where there is no large difference between the etching rates for the second resist pattern 322 and the second film 320, this leads to sequential removals of the second resist pattern 322 and the second film 320 at the position where the fifth opening 324 is formed when the second film 320 is etched. This means that, when the fifth opening 324 is formed by the etching, the second resist pattern 322 and the second film 320 at the position where the fifth opening 324 is formed are eliminated except for residues. The residues of the second resist pattern 322 and the second film 320 may be removed as necessary.

The contact hole 317 is formed by removing a part of the second insulating film 312, a part of the first insulating film 303, and a part of the gate insulating film 302 after the second resist pattern 322 is removed from the configuration illustrated in FIG. 7F. The contact hole 317 is formed so as to extend through the second insulating film 312, the first insulating film 303, and the gate insulating film 302 to expose the floating diffusion portion 309 to outside.

The contact hole 317 in communication with the fifth opening 324 is formed by conducting anisotropic etching on the second insulating film 312 with a reactive ion etching apparatus using the first film 314 as a mask. If the second film 320 is highly resistant to the etching at the time of this etching, the second film 320 can remain as illustrated in FIG. 7G. In this case, a sixth opening 325 is formed by removing the second film 320 after forming the contact hole 317 as illustrated in FIG. 7H.

However, in a case where there is no large difference between the etching rates for the second film 320 and the second insulating film 312, this leads to sequential removals of the second film 320 and the second insulating film 312 at the position where the contact hole 317 is formed when the second insulating film 312 is etched. This means that, when the contact hole 317 is formed by the etching, the second film 320 and the second insulating film 312 at the position where the contact hole 317 is formed are eliminated except for residues as illustrated in FIG. 7H. The residues of the second film 320 and the second insulating film 312 may be removed as necessary.

After that, a contact plug 326 and the light shielding film 304 can be formed by embedding a conductor in the contact hole 317 and the sixth opening 325 similarly to the above-described method.

According to the method, the present embodiment can increase the flatness of the upper surface of the photoresist, thereby improving the accuracy of forming the resist pattern. In other words, the present embodiment can improve the accuracy of forming the contact hole. In this manner, the method for forming the contact hole according to the present embodiment allows the contact hole to be accurately formed.

### Fourth Embodiment

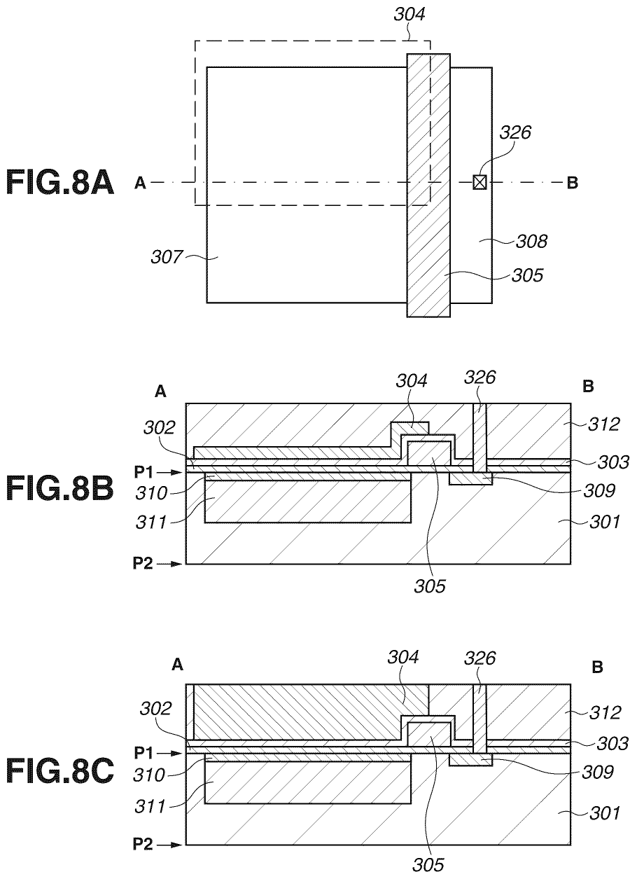

The present embodiment will be described regarding a semiconductor device manufactured by the manufacturing method according to any of the first to third embodiments. FIGS. 8A, 8B, and 8C are schematic views illustrating the semiconductor device according to the fourth embodiment including pixels in which the photoelectric conversion portion is partially covered with the light shielding film for focus detection. In the following description, the present embodiment will be described, omitting the detailed descriptions of configurations and processes similar to FIGS. 4A to 7I.

FIG. 8A is a plan view of the surface P1 of the semiconductor device. In FIG. 8A, light is prevented from being incident on a part of the photoelectric conversion portion 307 covered with the light shielding film 304. On the other hand, light is incident on another part of the photoelectric conversion portion 307 not covered with the light shielding film 304.

FIG. 8B is a cross-sectional view of the semiconductor device in an AB cross section illustrated in FIG. 8A. FIG. 8B illustrates the semiconductor device manufactured by the manufacturing method according to the second embodiment.

FIG. 8C is a cross-sectional view of the semiconductor device in the AB cross section illustrated in FIG. 8A. FIG. 8C illustrates the semiconductor device manufactured by the manufacturing method according to the third embodiment.

Employing the method for forming the contact hole described in the first to third embodiments also allows the control hole to be accurately formed in the manufacturing of the semiconductor device including the pixels in which the photoelectric conversion portion is partially covered with the light shielding film, as in the present embodiment.

### Fifth Embodiment

The present embodiment will be described regarding an application example using the semiconductor device manufactured by the manufacturing method according to any of the first to third embodiments. A semiconductor device 910 is assumed to be, for example, a complementary metal-oxide semiconductor (CMOS) image sensor.

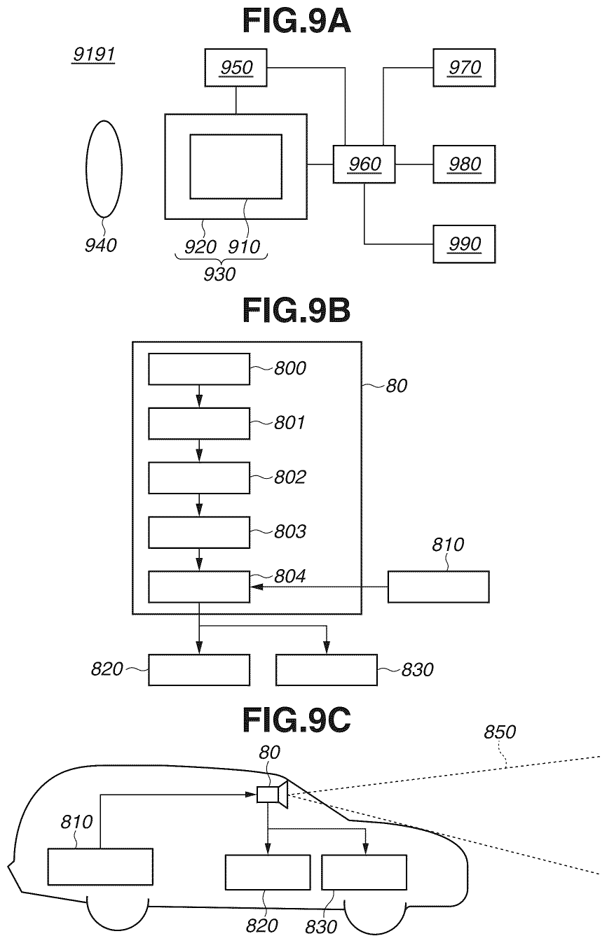

FIG. 9A is a schematic view illustrating an apparatus 9191, which is the application example. The apparatus 9191 includes a semiconductor apparatus 930. The semiconductor apparatus 930 includes a semiconductor device 910 and a package 920 containing the semiconductor device 910. The semiconductor device 910 can be manufactured by the manufacturing methods according to the other embodiments. The package 920 can include a substrate on which the semiconductor device 910 is fixed, and a cover member, such as glass, facing the semiconductor device 910. The package 920 can further include a bonding member, such as a bonding wire and a bump, connecting a terminal provided on the substrate and a terminal provided on the semiconductor device 910.

The apparatus 9191 can include at least any of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 is, for example, a lens, a shutter, and a mirror, and includes an optical system that guides light to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus such as a CPU or an ASIC, used to configure an analog front end (AFE) or a digital front end (DFE). The display apparatus 970 is an electro-luminescence (EL) display apparatus or a liquid crystal display apparatus that displays information (an image) acquired by the semiconductor apparatus 930. The storage apparatus 980 is a magnetic device or a semiconductor device that stores the information (the image) acquired by the semiconductor apparatus 930. The storage apparatus 980 is a volatile memory, such as a static random access memory (SRAM) or a dynamic random access memory (DRAM), or a nonvolatile memory, such as a flash memory or a hard disk drive.

The mechanical apparatus 990 includes a movable unit or a propulsion unit, such as a motor or an engine. The apparatus 9191, for example, displays the signal output from the semiconductor apparatus 930 on the display apparatus 970 or transmits the signal to outside using a communication apparatus (not illustrated) included in the apparatus 9191. To fulfill this function, the apparatus 9191 can further include the storage apparatus 980 and the processing apparatus 960 separately from a storage circuit and an arithmetic circuit included in the semiconductor apparatus 930. The mechanical apparatus 990 may be controlled based on the signal output from the semiconductor apparatus 930.

Further, the apparatus 9191 is suitable for an electronic apparatus such as an information terminal having an imaging function (for example, a smart-phone and a wearable terminal) or a camera (for example, an interchangeable-lens camera, a compact camera, a video camera, or a monitoring camera). The mechanical apparatus 990 in the camera can drive a component of the optical apparatus 940 for zooming, focusing, and a shutter operation. Alternatively, the mechanical apparatus 990 in the camera can move the semiconductor apparatus 930 for a vibration damping operation.

Further, the apparatus 9191 can be a transportation apparatus, such as a vehicle, a ship, or an airplane. The mechanical apparatus 990 in the transportation apparatus can be used as a movement apparatus. The apparatus 9191, serving as the transportation apparatus, can be applied to an apparatus that transports the semiconductor apparatus 930 or an apparatus that assists and/or automates the driving (maneuvering) using the imaging function. The processing apparatus 960 for assisting and/or automating the driving (maneuvering) can perform processing for operating the mechanical apparatus 990, serving as the movement apparatus, based on the information acquired by the semiconductor apparatus 930. Alternatively, the apparatus 9191 may be a medical appliance such as an endoscope, a measurement instrument such as a ranging sensor, an analytical instrument such as an electronic microscope, an office appliance such as a copying machine, or industrial equipment such as a robot.

According to the above-described embodiment, the apparatus 9191 allows excellent pixel characteristics to be achieved. Therefore, the value of the semiconductor apparatus can be enhanced. Enhancing the value described here refers to at least any of the addition of a function, the improvement of the performance, the improvement of the characteristics, the improvement of the reliability, the improvement of the manufacturing yield, a reduction in the environmental load, a cost reduction, a size reduction, and a weight reduction.

Therefore, even the value of the apparatus 9191 can be enhanced by using the semiconductor apparatus 930 according to the present embodiment for the apparatus 9191. For example, an excellent performance can be acquired when the semiconductor apparatus 930 is mounted on the transportation apparatus to capture an image outside the transportation apparatus and measure the external environment. Therefore, in the manufacturing and sales of the transportation apparatus, the decision to incorporate the semiconductor apparatus 930 according to the present embodiment into the transportation apparatus is advantageous in enhancing the performance of the transportation apparatus itself. Especially, the semiconductor apparatus 930 can be used for a transportation apparatus in which driving is assisted and/or automated using the information acquired by the semiconductor apparatus.

Next, a movable body will be described as another application example. FIG. 9B illustrates an example of a photoelectric conversion system regarding an on-vehicle camera. A photoelectric conversion system 80 includes a semiconductor device 800. The semiconductor device 800 is, for example, a photoelectric conversion device (an imaging device). The photoelectric conversion system 80 includes an image processing unit 801, which performs image processing on a plurality of pieces of image data acquired by the semiconductor device 800, and a parallax acquisition unit 802, which calculates a parallax (a phase difference between parallax images) from the plurality of pieces of image data acquired by the photoelectric conversion system 80.

Then, the photoelectric conversion system 80 may include, for example, a not-illustrated optical system that guides light to the semiconductor device 800, such as a lens, a shutter, and a mirror. Further, a plurality of photoelectric conversion portions approximately conjugate to a pupil of the optical system may be disposed in pixels included in the semiconductor device 800. For example, the plurality of photoelectric conversion portions approximately conjugate to the pupil is disposed corresponding to one micro lens. The plurality of photoelectric conversion portions receives light fluxes that have transmitted through positions different from each other in the pupil of the optical system, by which the semiconductor device 800 outputs image data corresponding to the light fluxes transmitted through the different positions. Then, the parallax acquisition unit 802 may calculate a parallax using the output image data. Further, the photoelectric conversion system 80 includes a distance acquisition unit 803, which calculates a distance to a target object based on the calculated parallax, and a collision determination unit 804, which determines whether there is a collision possibility based on the calculated distance. Here, the parallax acquisition unit 802 and the distance acquisition unit 803 are an example of a distance information acquisition unit that acquires distance information to the target object. In other words, the distance information refers to information regarding a parallax, a defocus amount, a distance to the target object, and/or the like. The collision determination unit 804 may determine the collision possibility by using any of these pieces of distance information. The distance information may be acquired by using Time of Flight (ToF). The distance information acquisition unit may be realized by dedicatedly designed hardware or may be realized by a software module. Alternatively, the distance information acquisition unit may be realized by a field programmable gate array (FPGA), an ASIC, or the like, or may be realized by a combination of them.

The photoelectric conversion system 80 is connected to a vehicle information acquisition apparatus 810, and can acquire vehicle information, such as a vehicle speed, a yaw rate, and a steering angle. Further, the photoelectric conversion system 80 is connected to a control electronic control unit (ECU) 820, which is a control apparatus that outputs a control signal for generating a braking force on the vehicle based on a result of the determination by the collision determination unit 804. Further, the photoelectric conversion system 80 is also connected to a warning apparatus 830, which issues a warning to a driver based on the result of the determination by the collision determination unit 804. For example, when the collision possibility is high as the result of the determination by the collision determination unit 804, the control ECU 820 controls the vehicle so as to avoid the collision or reduce damage by, for example, braking the vehicle, returning an accelerator, and/or reducing an engine output. The warning apparatus 830 warns the user by, for example, producing a warning sound or the like, displaying warning information on a screen of a car navigation system or the like, and/or vibrating a seat belt or a steering wheel.

In the present embodiment, surroundings of the vehicle, such as a scenery ahead of or behind the vehicle, are imaged by the photoelectric conversion system 80. FIG. 9C illustrates the photoelectric conversion system 80 in the case where it captures the image ahead of the vehicle (an imaging range 850). The vehicle information acquisition apparatus 810 transmits an instruction to the photoelectric conversion system 80 or the semiconductor device 800. Due to such a configuration, the distance can be measured with further improved accuracy.

In the above description, the photoelectric conversion system 80 has been described referring to the example that performs control so as to prevent the vehicle from colliding with another vehicle, but is also applicable to control for autonomously driving the vehicle so as to cause the vehicle to follow another vehicle, control for autonomously driving the vehicle so as to prevent the vehicle from departing from a traffic lane, or the like. Further, the photoelectric conversion system 80 is applicable to not only the vehicle such as the automobile, but also a movable body (a movable apparatus) such as a ship, an airplane, or an industrial robot. This movable body includes one or both of a driving force generation unit that generates a driving force mainly used to move this movable body, and a rotational body mainly used to move this movable body. The driving force generation unit can be an engine, a motor, or the like. The rotational body can be a tire, a wheel, a screw of a ship, a propeller, or the like. In addition, the photoelectric conversion system 80 is applicable to not only the movable body but also an apparatus broadly using object recognition, such as an intelligent transportation system (ITS).

The apparatus in the present embodiment can be a transportation apparatus, such as a vehicle, a ship, or a flight vehicle. The mechanical apparatus in the transportation apparatus can be used as a movement apparatus. The apparatus as the transportation apparatus can be applied to an apparatus that transports the semiconductor apparatus, or an apparatus in which the driving (the manipulation) is assisted and/or automated using the imaging function. The processing apparatus for assisting and/or automating the driving (the manipulation) can perform processing for operating the mechanical apparatus serving as the movement apparatus based on the information acquired by the semiconductor apparatus.

The present embodiment has been described citing the photoelectric conversion device as an example of the semiconductor device, but the semiconductor device may be another semiconductor device or may be both of them.

In the above-described manner, according to the present disclosure, the contact hole can be formed with improved accuracy.

According to the present disclosure, it is possible to improve the formation accuracy of the contact hole.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-160825, filed Sep. 18, 2024, which is hereby incorporated by reference herein in its entirety.

What is claimed is:

1. A method for forming a contact hole, comprising:
forming a light shielding film on a substrate;
forming a first film having a flat upper surface by applying a precursor on the substrate in such a manner that an application amount of the precursor is smaller on the light shielding film than on another portion; and
patterning the first film when forming the contact hole.

2. The method for forming the contact hole according to claim 1, wherein the forming the first film includes planarizing an upper surface of the precursor and curing the precursor in such a manner that the precursor has a flat upper surface.

3. The method for forming the contact hole according to claim 1, wherein the contact hole is formed in the first film.

4. The method for forming the contact hole according to claim 3, further comprising:
forming a resist pattern by forming a photoresist film on the first film and performing extreme ultraviolet (EUV) exposure; and
forming the contact hole in the first film by etching the first film using the resist pattern as a mask.

5. The method for forming the contact hole according to claim 4, wherein the EUV exposure has a numerical aperture NA greater than 0.55.

6. The method for forming the contact hole according to claim 1, further comprising forming an insulating layer on the light shielding film,
wherein the forming the first film includes forming the first film on the insulating layer.

7. The method for forming the contact hole according to claim 6, wherein the contact hole is formed in the insulating layer.

8. The method for forming the contact hole according to claim 7, further comprising:
forming a resist pattern by forming a photoresist film on the first film and performing extreme ultraviolet (EUV) exposure;
etching the first film using the resist pattern as a mask; and
forming the contact hole in the insulating layer by etching the insulating layer.

9. The method for forming the contact hole according to claim 8, wherein the EUV exposure has a numerical aperture NA greater than 0.55.

10. The method for forming the contact hole according to claim 1, further comprising forming a photoelectric conversion portion configured to generate a charge according to incident light, a charge holding portion configured to accumulate the charge transferred from the photoelectric conversion portion, a floating diffusion portion configured to receive the charge transferred from the charge holding portion, a first transfer transistor configured to transfer the charge from the photoelectric conversion portion to the charge holding portion, and a second transfer transistor configured to transfer the charge from the charge holding portion to the floating diffusion portion on the substrate,
wherein the contact hole is formed so as to expose the floating diffusion portion to outside.

11. The method for forming the contact hole according to claim 10, wherein the light shielding film is formed so as to cover at least a part of a gate electrode of the first transfer transistor, at least a part of a gate electrode of the second transfer transistor, and at least a part of the charge holding portion.

12. The method for forming the contact hole according to claim 1, further comprising forming a photoelectric conversion portion configured to generate a charge according to incident light, a floating diffusion portion configured to receive the charge transferred from the photoelectric conversion portion, and a first transfer transistor configured to transfer the charge from the photoelectric conversion portion to the floating diffusion portion on the substrate,
wherein the contact hole is formed so as to expose the floating diffusion portion to outside.

13. The method for forming the contact hole according to claim 12, wherein the light shielding film is formed so as to cover at least a part of the photoelectric conversion portion and at least a part of a gate electrode of the first transfer transistor.

14. The method for forming the contact hole according to claim 1, wherein the forming the first film includes applying the precursor in such a manner that the application amount of the precursor is smaller on the light shielding film than on a portion between a plurality of light shielding films including the light shielding film.

15. A method for forming a contact hole, comprising:
forming a first film having a flat upper surface by applying a first precursor on an insulating layer disposed on a gate electrode of a transistor in such a manner that an application amount of the first precursor is smaller on the gate electrode than on another portion;
patterning the first film disposed on the gate electrode;
patterning the insulating layer disposed on the gate electrode;
forming a second film having a flat upper surface by applying a second precursor on a substrate with the gate electrode and the insulating layer disposed thereon in such a manner that an application amount of the second precursor is larger on the gate electrode than on another portion; and
patterning the second film when forming the contact hole in the insulating layer.

16. The method for forming the contact hole according to claim 15, wherein the forming the first film includes planarizing an upper surface of the first precursor and curing the first precursor in such a manner that the first precursor has a flat upper surface, and
wherein the forming the second film includes planarizing an upper surface of the second precursor and curing the second precursor in such a manner that the second precursor has a flat upper surface.

17. The method for forming the contact hole according to claim 15, further comprising:
forming a first resist pattern by forming a photoresist film on the first film and performing extreme ultraviolet (EUV) exposure;
etching the first film using the first resist pattern as a mask;
forming a second resist pattern by forming a photoresist film on the second film and performing EUV exposure; and
etching the second film using the second resist pattern as a mask.

18. The method for forming the contact hole according to claim 17, wherein the EUV exposure has a numerical aperture NA greater than 0.55.

19. A method for manufacturing a semiconductor device, comprising:
forming a light shielding film on a substrate;
forming a first film having a flat upper surface by applying a precursor on the substrate in such a manner that an application amount of the precursor is smaller on the light shielding film than on another portion; and
forming a contact hole by patterning the first film.

20. The method for manufacturing the semiconductor device according to claim 19, wherein the contact hole is formed in the first film.
